(19) United States
(12) Patent Application Publication
(10) Pub. No.: US 2026/0092829 A1
(43) Pub. Date: Apr. 2, 2026

(54) OPTICAL LEAK DETECTION IN LIQUID COOLING SYSTEMS USING HOLOGRAPHIC OPTICAL ELEMENT

(71) Applicant: DELL PRODUCTS L.P., Round Rock, TX (US)

(72) Inventors: James L. Petivan, III, Austin, TX (US); Sandor Farkas, Round Rock, TX (US)

(21) Appl. No.: 18/900,761

(22) Filed: Sep. 29, 2024

(51) Int. Cl. G01M 3/38; H05K 7/20

(52) U.S. Cl. CPC G01M 3/38; H05K 7/20772

(57) ABSTRACT

An apparatus includes a holographic optical element (HOE) and an optical sensor. The HOE is configured to have an interference pattern that functions as mirrors in an inverted server when illuminated by a light source. The HOE is placed on a bottom surface of the inverted server. The optical sensor is directed at the HOE and configured to detect a fluorescent light emitted from a liquid drop at a first wavelength when illuminated by the light source. The liquid drop lands on the HOE from a cooling liquid. The interference pattern is created by a laser beam operating to form a hologram at a second wavelength substantially close to the first wavelength.

### FIELD OF THE DISCLOSURE

This disclosure generally relates to information handling systems, and more particularly relates to optical leak detection in liquid cooling systems using holographic optical element.

### BACKGROUND

As the value and use of information continues to increase, individuals and businesses seek additional ways to process, store, and display information. One option is an information handling system. An information handling system generally processes, compiles, stores, communicates and/or display information or data for business, personal, or other purposes. Because technology and information handling needs and requirements may vary between different applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, reservations, enterprise data storage, or global communications. In addition, information handling systems may include a variety of hardware and software resources that may be configured to process, store, display, and communicate information and may include one or more computer systems, data storage systems, and networking systems.

### SUMMARY

An apparatus includes a holographic optical element (HOE) and an optical sensor. The HOE is configured to have an interference pattern that functions as mirrors in an inverted server when illuminated by a light source. The HOE is placed on a bottom surface of the inverted server. The optical sensor is directed at the HOE and configured to detect a fluorescent light emitted from a liquid drop at a first wavelength when illuminated by the light source. The liquid drop lands on the HOE from a cooling liquid. The interference pattern is created by a laser beam operating to form a hologram at a second wavelength substantially close to the first wavelength.

### BRIEF DESCRIPTION OF THE DRAWINGS

It will be appreciated that for simplicity and clarity of illustration, elements illustrated in the Figures have not necessarily been drawn to scale. For example, the dimensions of some of the elements are exaggerated relative to other elements. Embodiments incorporating teachings of the present disclosure are shown and described with respect to the drawings presented herein, in which:

FIG. 1 is a diagram illustrating an information handling system according to an embodiment of the present disclosure

FIG. 2 is a block diagram illustrating a server system according to an embodiment of the present disclosure;

FIG. 3 is a diagram illustrating a server having a holographic optical leak detector according to an embodiment of the present disclosure;

FIG. 4 is a diagram illustrating a configuration of virtual mirrors according to an embodiment of the present disclosure;

FIG. 5 is a diagram illustrating a configuration of creating the HOE with virtual mirrors according to an embodiment of the present disclosure;

FIG. 6 is a diagram illustrating a configuration of creating the HOE with a diffuse mirror according to an embodiment of the present disclosure;

FIG. 7 is a flowchart illustrating a process for holographic optical leak detection according to an embodiment of the present disclosure.

The use of the same reference symbols in different drawings indicates similar or identical items.

### DETAILED DESCRIPTION OF DRAWINGS

The following description in combination with the Figures is provided to assist in understanding the teachings disclosed herein. The following discussion will focus on specific implementations and embodiments of the teachings. This focus is provided to assist in describing the teachings, and should not be interpreted as a limitation on the scope or applicability of the teachings. However, other teachings can certainly be used in this application. The teachings can also be used in other applications, and with several different types of architectures, such as distributed computing architectures, client/server architectures, or middleware server architectures and associated resources.

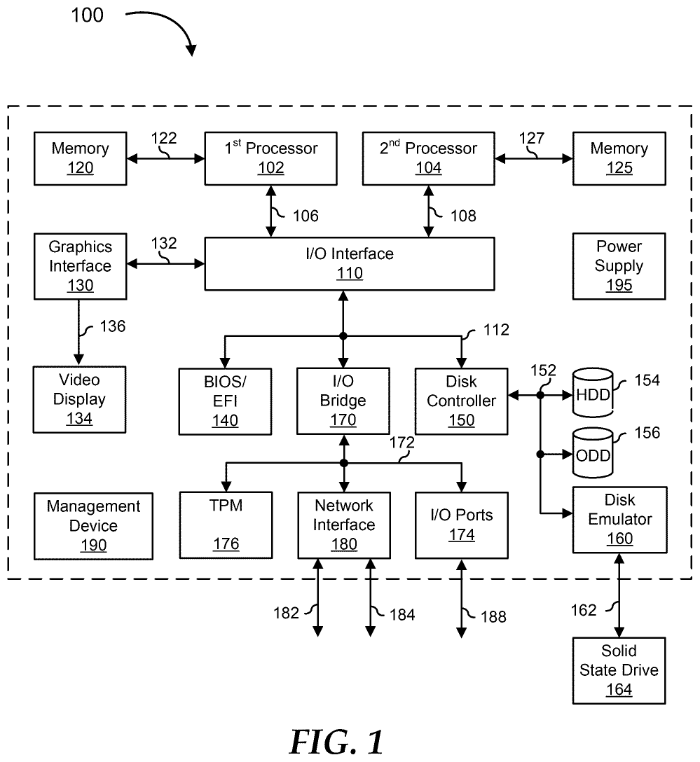

FIG. 1 is a diagram illustrating an information handling system 100 according to an embodiment of the present disclosure.

For purpose of this disclosure an information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. The term “information handling system” may refer to a processing system, a control circuit, a control processor, or any processing apparatus that processes or handles information, data, or control or status words. For example, information handling system 100 can be a personal computer, a laptop computer, a smart phone, a tablet device or other consumer electronic device, a network server, a network storage device, a switch router or other network communication device, or any other suitable device and may vary in size, shape, performance, functionality, and price. Further, information handling system 100 can include processing resources for executing machine-executable code, such as a central processing unit (CPU), a programmable logic array (PLA), an embedded device such as a System-on-a-Chip (SoC), or other control logic hardware. Information handling system 100 can also include one or more computer-readable medium for storing machine-executable code, such as software or data. Additional components of information handling system 100 can include one or more storage devices that can store machine-executable code, one or more communications ports for communicating with external devices, and various input and output (I/O) devices, such as a keyboard, a mouse, and a video display. Information handling system 100 can also include one or more buses operable to transmit information between the various hardware components.

Information handling system 100 can include devices or modules that embody one or more of the devices or modules described in this disclosure, and operates to perform one or more of the methods described in this disclosure. Information handling system 100 may include more or less than the components described in the following. Information handling system 100 includes first and second processors 102 and 104, an input/output (I/O) interface 110, memories 120 and 125, a graphics interface 130, a basic input and output system/universal extensible firmware interface (BIOS/UEFI) module 140, a disk controller 150, a hard disk drive (HDD) 154, an optical disk drive (ODD) 156, a disk emulator 160 connected to an external solid state drive (SSD) 164, an I/O bridge 170, one or more add-on resources 174, a trusted platform module (TPM) 176, a network interface 180, a management device 190, and a power supply 195. Processors 102 and 104, I/O interface 110, memory 120, graphics interface 130, BIOS/UEFI module 140, disk controller 150, HDD 154, ODD 156, disk emulator 160, SSD 164, I/O bridge 170, add-on resources 174, TPM 176, and network interface 180 operate together to provide a host environment of information handling system 100 that operates to provide the data processing functionality of the information handling system. The host environment operates to execute machine-executable code, including platform BIOS/UEFI code, device firmware, operating system code, applications, programs, and the like, to perform the data processing tasks associated with information handling system 100.

In the host environment, processor 102 is connected to I/O interface 110 via processor interface 106, and processor 104 is connected to the I/O interface via processor interface 108. Memory 120 is connected to processor 102 via a memory interface 122. Memory 125 is connected to processor 104 via a memory interface 127. Graphics interface 130 is connected to I/O interface 110 via a graphics interface 132, and provides a video display output 136 to a video display 134. In a particular embodiment, information handling system 100 includes separate memories that are dedicated to each of processors 102 and 104 via separate memory interfaces. An example of memories 120 and 125 include random access memory (RAM) such as static RAM (SRAM), dynamic RAM (DRAM), non-volatile RAM (NV-RAM), or the like, read only memory (ROM), another type of memory, or a combination thereof. Processor 102 and/or processor 104 may process data or information to be displayed on a monitor.

BIOS/UEFI module 140, disk controller 150, and I/O bridge 170 are connected to I/O interface 110 via an I/O channel 112. An example of I/O channel 112 includes a Peripheral Component Interconnect (PCI) interface, a PCI-Extended (PCI-X) interface, a high-speed PCI-Express (PCIe) interface, another industry standard or proprietary communication interface, or a combination thereof. I/O interface 110 can also include one or more other I/O interfaces, including an Industry Standard Architecture (ISA) interface, a Small Computer Serial Interface (SCSI) interface, an Inter-Integrated Circuit (I²C) interface, a System Packet Interface (SPI), a Universal Serial Bus (USB), another interface, or a combination thereof. BIOS/UEFI module 140 includes code that operates to detect resources within information handling system 100, to provide drivers for the resources, to initialize the resources, and to access the resources.

Disk controller 150 includes a disk interface 152 that connects the disk controller to HDD 154, to ODD 156, and to disk emulator 160. An example of disk interface 152 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 160 permits SSD 164 to be connected to information handling system 100 via an external interface 162. An example of external interface 162 includes a USB interface, an IEEE 1394 (Firewire) interface, a proprietary interface, or a combination thereof. Alternatively, solid-state drive 164 can be disposed within information handling system 100.

I/O bridge 170 includes a peripheral interface 172 that connects the I/O bridge to I/O port or add-on resource 174, to TPM 176, and to network interface 180. Peripheral interface 172 can be the same type of interface as I/O channel 112 or can be a different type of interface. As such, I/O bridge 170 extends the capacity of I/O channel 112 where peripheral interface 172 and the I/O channel are of the same type, and the I/O bridge translates information from a format suitable to the I/O channel to a format suitable to the peripheral channel 172 where they are of a different type. I/O port 174 can include I/O lines 188 to interface to a parallel or serial I/O channel, a data storage system, an additional graphics interface, a network interface card (NIC), a sound/video processing card, another add-on resource, or a combination thereof. I/O port 174 can be on a main circuit board, on separate circuit board or add-in card disposed within information handling system 100, a device that is external to the information handling system, or a combination thereof.

Network interface 180 represents a NIC disposed within information handling system 100, on a main circuit board of the information handling system, integrated onto another component such as I/O interface 110, in another suitable location, or a combination thereof. Network interface device 180 includes network channels 182 and 184 that provide interfaces to devices that are external to information handling system 100. In a particular embodiment, network channels 182 and 184 are of a different type than peripheral channel 172 and network interface 180 translates information from a format suitable to the peripheral channel to a format suitable to external devices. An example of network channels 182 and 184 includes InfiniBand channels, Fibre Channel channels, Gigabit Ethernet channels, proprietary channel architectures, or a combination thereof. Network channels 182 and 184 can be connected to external network resources (not illustrated). The network resource can include another information handling system, a data storage system, another network, a grid management system, another suitable resource, or a combination thereof.

Management device 190 represents one or more processing devices, such as a dedicated baseboard management controller (BMC), System-on-a-Chip (SoC) device, one or more associated memory devices, one or more network interface devices, a complex programmable logic device (CPLD), and the like, that operate together to provide the management environment for information handling system 100. In particular, management device 190 is connected to various components of the host environment via various internal communication interfaces, such as a Low Pin Count (LPC) interface, an Inter-Integrated-Circuit (I2C) interface, a PCIe interface, or the like, to provide an out-of-band (OOB) mechanism to retrieve information related to the operation of the host environment, to provide BIOS/UEFI or system firmware updates, to manage non-processing components of information handling system 100, such as system cooling fans and power supplies. Management device 190 can include a network connection to an external management system, and the management device can communicate with the management system to report status information for information handling system 100, to receive BIOS/UEFI or system firmware updates, or to perform other task for managing and controlling the operation of information handling system 100. Management device 190 can operate off of a separate power plane from the components of the host environment so that the management device receives power to manage information handling system 100 where the information handling system is otherwise shut down. An example of management device 190 include a commercially available BMC product or other device that operates in accordance with an Intelligent Platform Management Initiative (IPMI) specification, a Web Services Management (WSMan) interface, a Redfish Application Programming Interface (API), another Distributed Management Task Force (DMTF), or other management standard, and can include an Integrated Dell Remote Access Controller (iDRAC), an Embedded Controller (EC), or the like. Management device 190 may further include associated memory devices, logic devices, security devices, or the like, as needed or desired.

As technology becomes advanced, information handling systems become increasingly complex. To meet demands for high performance, information handling systems are packed with a large amount of semiconductor chips, computing circuits, and many peripheral and interfacing elements. Such systems typically consume a lot of power and generate excessive heat that may cause diminished quality and even damage to the systems. To reduce heat, cooling techniques have been developed. Among various cooling techniques, liquid cooling has been increasingly popular due to its energy efficiency, performance effectiveness, and low cost. Liquid cooling techniques, however, may create problems such as leaks. Leak detection, control and management, therefore, is useful to maintain the integrity of the cooling system in high computing environments such as complex information handling systems, artificial intelligence (AI) platforms, and data centers.

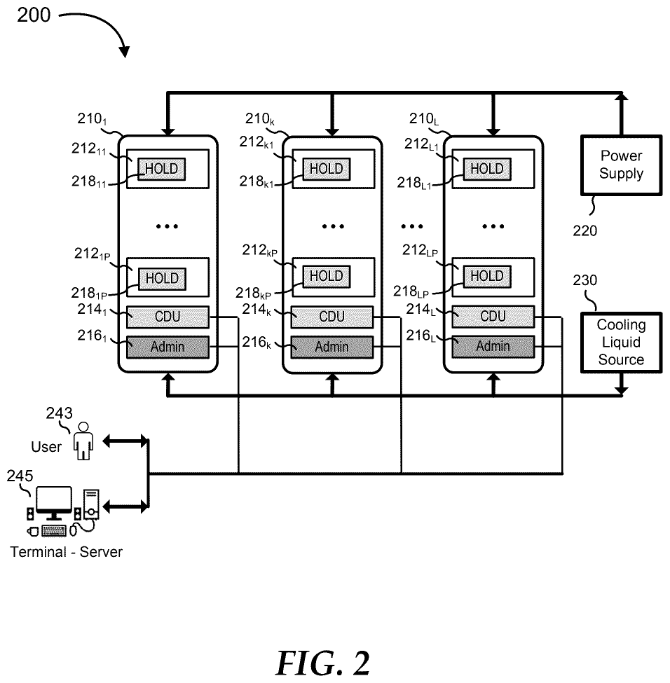

FIG. 2 is a block diagram illustrating a system 200 according to an embodiment of the present disclosure. The system 200 may be or include the information handling system 100 shown in FIG. 1. The system 200 may be a multiprocessor computer system, a high-performance computing (HPC) system, a large network center, a cluster of servers, a data center, an artificial intelligence (AI) system, edge computing, cloud computing, network servers, or any large electronic systems with high power consumption. The system 200 typically employs thousands of semiconductor devices such as central processing units (CPUs), graphical processing units (GPUs), and memory chips. The system 200 may include L rack, or rack-mounted, servers 210ₖ's, where k=1, . . . , L, a power supply 220, and a cooling liquid source 230. L is a positive integer with a value depending on the configuration of the system 200. The system 200 may include more or less than the above components. In the following, the subscript index k may be dropped for clarity.

The L rack servers 210ₖ's may be located in a single room, in several rooms, or scattered throughout a building, on the same floor or on different floors. The system 200 shown in FIG. 2 may have identical L rack servers 210ₖ's for illustrative purposes only. They may be the same or have different configurations. They may be part of clusters of processors in a highly parallel system or they may be established for specific applications such as medical, scientific research, or business enterprise. As an example, a server may be dedicated to intensive computing, another may serve to store data, yet another may focus on graphical display and animation. They may work as standalone subsystems or connected to one another via a local area network (LAN) or wide area network (WAN). The L rack servers 210ₖ's represent an example of an HPC system. The system 200 may include components that are packaged or assembled in any convenient format, and not necessarily to be mounted on racks, slots, or bays. The L rack servers 210ₖ's typically consume a large amount of power during active periods. Because of this high power consumption, the L rack servers 210ₖ's generate an excessive amount of heat. Accordingly, a cooling technique is employed to cool the system and to prevent overheating that may cause performance degradation or damage to the system. In one embodiment, the cooling technique used in the system 200 is liquid cooling.

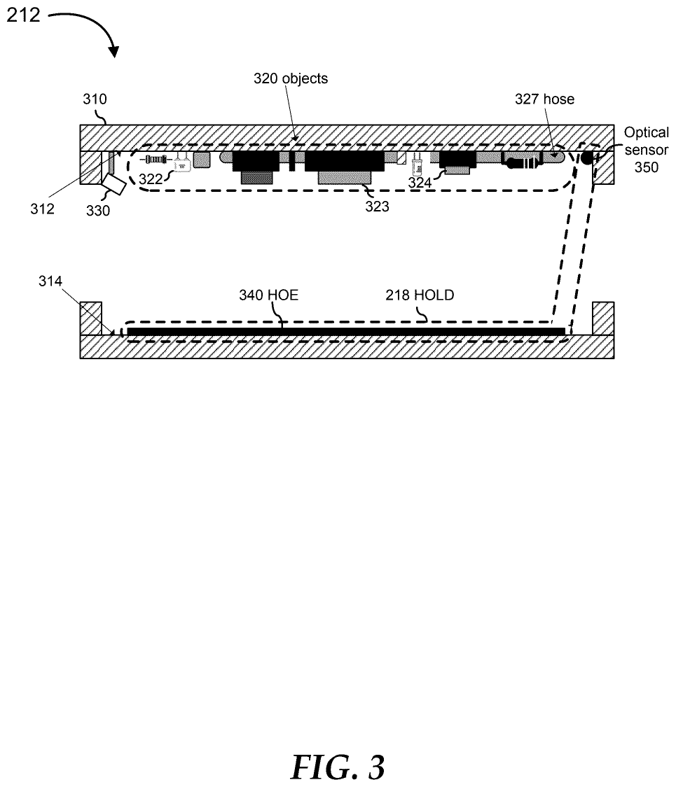

Each of the L rack servers 210ₖ's includes a number of servers 212ₖⱼ's where k=1, . . . , L and j=1, . . . , P (P is a positive integer having a predetermined value), a cooling distribution unit (CDU) 214ₖ and an administration server 216ₖ. The servers 212ₖⱼ's are mounted on slots in the rack or cabinet. In this illustrative example, a server is typically designed for continuous and heavy use. Each server may be populated with electronic devices such as CPUs, memories, storage, and peripheral devices. They may also include network switches, cable management systems, and appropriate mounting hardware. Each of the servers 212ₖⱼ's may include a holographic optical leak detector (HOLD) 218ₖⱼ. The HOLD 218ₖⱼ detects leaks in the hose using a holographic optical signal processing technique. The HOLD 218ₖⱼ will be described in FIG. 3.

The CDU 214ₖ distributes coolant throughout the rack server 210ₖ. It may include a pumping mechanism to circulate the coolant to the heat-generating components or cold plates placed on top of CPUs or GPUs. The CDU 214ₖ may operate together with coolant distribution manifolds (CDMs). The CDMs are distribution pipes that supply coolant to each server and collect the hotter coolant back to the CDU. Flexible hoses are used to carry the cooler liquid to the individual server at the ingress to the various sites on the server and return the hotter liquid to the associated CDM at the egress. These hoses are connected through various connectors and valves.

The administration server 216ₖ includes circuits that perform administration of the cooling policies and implementations. The administration includes the central control, management, and regulation of various components, or subsystems in the system 200. The administration server 216ₖ may communicate with the HOLD 218ₖⱼ to receive a leak detection status. It may also interact with a user 243 and/or a terminal or server 245. The user 243 may be any individual or entity responsible for the administration of the individual server in the L rack servers 210ₖ's or the system 200. The user 243 may receive status reports or alerts from the administration server 216ₖ and respond with commands or instructions to the administration server 216_{k.} The terminal or server 245 may include a processing circuit, software, or an application that has been designed to automatically respond to reports or alerts from the administration server 216ₖ.

The power supply 220 provides power to the L rack servers 210ₖ's in addition to other power needs for the facilities including lighting, cooling (e.g., air-conditioning), network load. The power supply 220 may include a typical power infrastructure including transformers, power distribution units (PDUs), power breakers, uninterruptible power supplies (UPSes), and backup generators.

The cooling liquid source 230 may include any suitable sources for liquid cooling including water and dielectric fluids. It may include coolant distribution units (CDUs), liquid cooled racks, indoor chilled water storage, and pumps. The cooling type may be direct-to-chip cooling and rear-door liquid cooling. In one embodiment, the system 200 utilizes the direct-to-chip cooling technique in which the cooling mechanisms are applied directly to the heat-generating components such as CPUs, GPUs, and memory chips. The cooling liquid source 230 delivers the coolant to each of the L rack servers 210ₖ's via the CDU 214ₖ's and CDMs.

FIG. 3 is a diagram illustrating the server 212 having the holographic optical leak detector (HOLD) 218 shown in FIG. 2 according to an embodiment of the present disclosure. For clarity, subscripts may be dropped. The server 212 includes a chassis or bay 310, objects 320, a light source 330, and the HOLD 218. The HOLD 218 includes a holographic optical element (HOE) 340 and an optical sensor 350. The server 212 and the HOLD 218 may include more or less than the above components.

The chassis 310 is configured to house the objects 320, the light source 330, and the HOLD 218. The objects 320 are populated on a platform 312 and the HOE 340 is placed on a surface 314. In a normal configuration without the HOLD 218, the platform 312 and the objects 320 are at the bottom of the chassis 310 and the surface 314 is at the top of the chassis 310. In an embodiment with the HOLD 218 as shown in FIG. 3, the chassis 310 is inverted, meaning it is turned upside down. In this configuration, the server 212 is referred to as an inverted server. The platform 312 is at the top and the surface 314 becomes a bottom surface. Since the objects 320 are secured firmly on the platform 312, in this inverted configuration they are not subject to gravity force to fall on the bottom surface 314. If necessary, any loose components may be fastened on the platform 312 by any means necessary such as adhesive or tape to avoid falling down. The only elements that may fall down and land on the bottom surface 314 are drops of the cooling liquid in the hose 327 due to a leak in the hose327. Therefore, this inverted configuration may allow drops of the cooling liquid to land on the bottom surface 314 without spreading through the objects 320 on the platform 312. Liquid spreading to the electronic components of the objects 320 may cause malfunction or damages to these components and compromise the operations of various circuits. Furthermore, by isolating the leaked liquid from the objects 320 and letting it land on the bottom surface 314 in the form of liquid drops, the detection of leakage is facilitated because the liquid drops are the only components on the bottom surface 314 which provides a clear and unobstructed scene to be captured or sensed by the optical sensor 350.

The objects 320 include components in a typical server or computing environment. These include integrated circuits, CPUs, GPUs, memories, digital and analog devices, active and passive devices, discrete devices (e.g., resistors, capacitors, inductors), and mechanical devices. They are populated on the surface 312 facing downward to the bottom surface 314. For illustrative purposes, the objects 320 include objects 322, 323, and 324. In particular, the objects 320 include a hose 327 that carries cooling liquid mixed with a fluorescent dye. The dye is used to provide an easily recognized color (e.g., green) to the cooling liquid when illuminated or excited by a light source such as ultraviolet (UV) light. In other words, the dye contains fluorophores that can be activated by UV light excitation and will fluoresce. The objects 320 are cooled by the cooling liquid flowing in the hose 327 that is placed through the objects. The hose 327 may be leaked at a crack, hole, or opening and dyed liquid drips through the crack to form drops dripping down to the bottom surface 314.

The light source 330 is used to illuminate the HOE 340 on the bottom surface 314 to detect a liquid drop. The presence of a liquid drop on the HOE 340 is an indication that a leak has occurred. The liquid is mixed with a fluorescent dye that is selected to match the wavelength or energy level of the light source. In one embodiment the light source is UV light source. Depending on the dye material, the light source 330 may be optional or light sources other than UV such as blue light may be used.

The HOLD 218 is the main component for leak detection. The HOE 340 is a recording material (e.g., a film) such as high-resolution photographic emulsions, photorefractive materials, photo-sensitive polymers and photoresists. The HOE 340 is configured to have an interference pattern that functions as mirrors when illuminated by the light source 330. The HOE 340 is placed on the bottom surface 314 facing upward to the objects 320. The interference pattern is created by a laser beam operating to form a hologram at a laser wavelength. The laser wavelength is selected to be close to the wavelength of the color of the dye so that the response on the HOE 340 is strengthened when the dye color is detected. In one embodiment, the laser wavelength may be within 5% to 10% of the dye wavelength.

The optical sensor 350 is directed at the HOE 340 and configured to detect a fluorescent light emitted from a liquid drop at a dye wavelength when illuminated by the light source 330. As mentioned above, when there is a leak, the liquid drop drips through the leak and lands on the HOE 340. The optical sensor 350 may be a sensor that is responsive to the dye color. It may be designed from photodiodes (PD), avalanche photodiodes (APD), phototransistors, photodiode arrays, charge coupled devices (CCD), Complementary Metal Oxide Semiconductor (CMOS) sensors, silicon (Si) Ref Green Blue (RGB color) sensors (blue 400-450 nm, green 495-570 nm, and red 590-720 nm), and the like.

The main use of the HOE 340 is to provide a way to collect as much as possible the light responses to the dye color. Using holographic means allows the reflected rays to be more focused to the optical sensor 350 when the optical sensor 350 is placed at a position close to the focal point of the mirrors represented by the interference pattern. Without the HOE 340, the reflected rays may be scattered and bouncing in random directions and therefore may not be collected efficiently at the optical sensor 350. One embodiment is to create the interference pattern to function as virtual mirrors that reflect the light rays to the optical sensor 350.

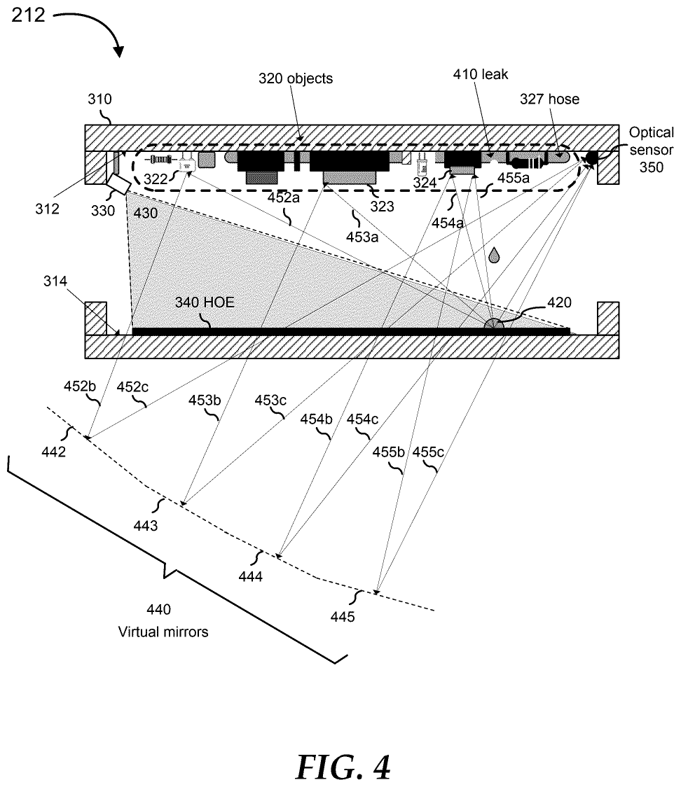

When there is no leak, no liquid drop is present on the HOE 340. Therefore, there is no dye. Assuming the dye color is green, when the light source 330 illuminates the HOE 340, there are no green light rays reflected to the objects 320 and light source 330 only provides reflected rays in a random manner without any collective strength for the green color. The optical sensor 350, by virtue of being configured to respond to the green color, simply returns a weak response that corresponds to a no leak condition. When there is a leak, the virtual mirrors help strengthen the response to the green color as shown in FIG. 4.

FIG. 4 is a diagram illustrating a configuration of virtual mirrors according to an embodiment of the present disclosure. When there is a leak, a liquid drop 420 lands on the HOE 340. When the light source illuminates the HOE 340 with a coverage range 430, the fluorescent rays emitted from the drop reach the objects 320. These rays then reflected to the virtual mirrors which reflect them to their focal points. The optical sensor 350 is placed in the vicinity of the focal points and therefore receives most of the reflected lights. The detection therefore is strengthened and the optical sensor 350 is able to detect the leak.

The virtual mirrors are captured in the interference pattern on the HOE 340 during the creation of a hologram on the HOE 340. There are as many virtual mirrors according to the number of objects and their arrangements and placements on the platform 312. FIG. 4 show virtual mirrors 440 which include mirrors 442, 443, 444, and 445 that reflect the four rays reflected from the objects 322, 323, and 324. The optical sensor 350 is positioned at or close to the focal points of the mirrors 442, 443, 444, and 445.

When the light source 330 illuminates the drop 420, the dye in the drop 420 fluoresces rays 452a, 453a, 454a, and 455a. Ray 452a strikes object 322 and is reflected as ray 452b which is reflected on mirror 442 as ray 452c pointing to the focal point of mirror 442. This focal point is close to the optical sensor 350. Ray 453a strikes object 323 and is reflected as ray 453b which is reflected on mirror 443 as ray 453c pointing to the focal point of mirror 443. This focal point is close to the optical sensor 350. Ray 454a strikes one corner of object 324 and is reflected as ray 454b which is reflected on mirror 444 as ray 454c pointing to the focal point of mirror 444. This focal point is close to the optical sensor 350. Ray 455a strikes another corner of object 324 and is reflected as ray 455b which is reflected on mirror 445 as ray 455c pointing to the focal point of mirror 445. This focal point is close to the optical sensor 350.

Since four green color rays converge to the optical sensor 350, the optical sensor 350 receives a high amount of green light. This collective high amount of green light is compared with a predetermined threshold and can easily exceed it. Therefore, it can reliably detect the leak.

The location of the focal points may not be determined accurately. However, the approximate or estimated location is sufficient to gather a large amount of green light. This is much better than detecting, without the HOE 340, many rays of green light that randomly reflects all over or bounces off surfaces inside the inverted server.

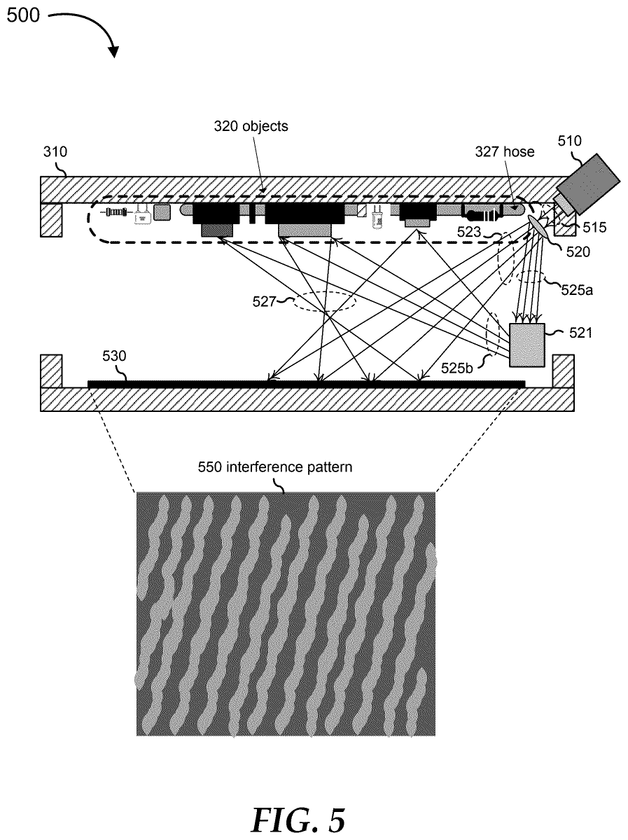

FIG. 5 is a diagram illustrating a configuration 500 of creating the HOE 340 with virtual mirrors according to an embodiment of the present disclosure. The configuration 500 includes a laser source 510, an optical assembly 520, a film or plate 530, the chassis 310 and the objects 320. The configuration 500 may include more or less than the above components.

The laser source 510 is configured to generate laser beams to create a hologram or the interference pattern on the HOE 340. It may be a single frequency laser, a tunable continuous-wave laser, a diode laser, or a pulsed solid-state laser. The wavelength that the laser source 510 operates is selected so that it is close to the wavelength of the fluorescent color of the dye mixed in the cooling liquid. For example, if the fluorescent color of the dye is green at a wavelength λ₁=495 nm to 570 nm, then the wavelength of the laser source 510 may be λ₂=500 nm to 600 nm. Embodiments that use other fluorescent colors (e.g., blue, red) may be similarly designed. By using the laser having a wavelength close to that of the dye color, the optical response upon the UV illumination will be strengthened and the reflected rays will be more focused on the virtual mirrors to provide strong collective response to the optical sensor 350.

The optical assembly 520 includes optical elements that help in the recording. In one embodiment, the laser source 510 and the optical assembly 520 are placed at the same location of the optical sensor 350 when it is used for leak detection.

The optical assembly 520 may include one or more lenses, a beam splitter, one or more mirrors, and other optical devices used in creating a hologram. An example is an optical mirror 521 that is used to direct the beams to the proper target. The optical mirror 521 may be placed at any convenient location. For illustrative purposes, the optical mirror 521 is shown in FIG. 5 to be positioned at a location different from the optical assembly 520. The laser source 510 generates laser beam 515 to the optical assembly 520. The optical assembly 520 splits the laser beam 515 into a reference beam 523 and an object beam 525a. The reference beam 523 illuminates the film 530. The object beam 525a reflects on the optical mirror 521 to become an object beam 525b which illuminates the objects 320 and reflects on the objects 320 to become the reflection beam 527. The reference beam 523 and the reflection beam 527 converge at the film 530 and together they create an interference pattern 550.

The film 530 is a film suitable for the creation of a hologram. It may include high-resolution photographic emulsions, photorefractive materials, photo-sensitive polymers and photoresists.

The interference pattern 550 may be considered an optical mapping of the objects 320 on the film 530. It therefore contains information on the geometry of the objects 320 including the formation of the reflected rays coming from the objects. Because of this, the interference pattern 550 may be considered as providing a means to reconstruct virtual mirrors that allow the reflection of rays bouncing off the objects as when it is illuminated with a light source as shown in FIG. 4. The interference pattern 550 may be a random pattern of dots and streaks as seen under normal light but it is in essence a physical model of the virtual mirrors associated with the objects 320 when it is illuminated by a light source having a wavelength that is close to the wavelength of the laser beam used to record the interference pattern 550.

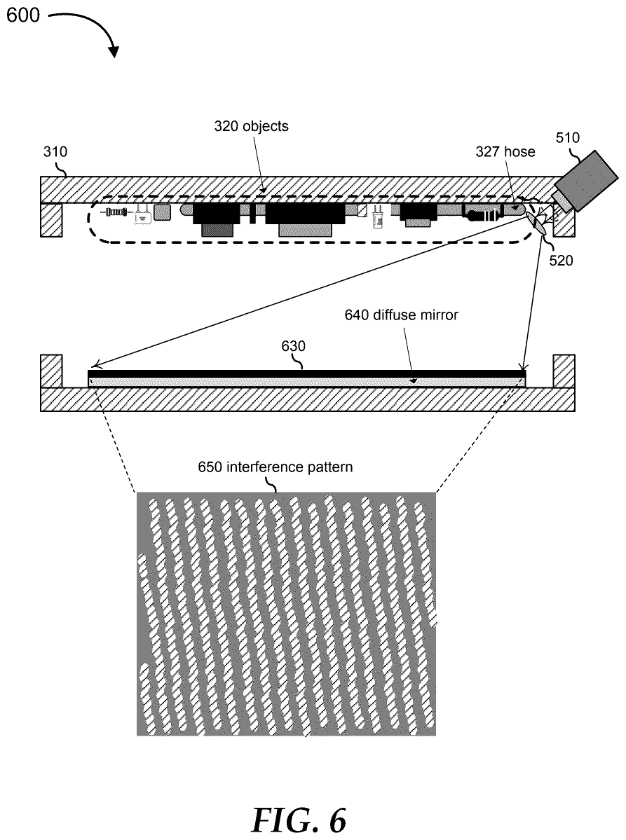

FIG. 6 is a diagram illustrating a configuration 600 of creating the HOE with a diffuse mirror according to an embodiment of the present disclosure. The configuration 600 includes a film or plate 630, a diffuse mirror 640, the laser source 510, the optical assembly 520, the chassis 310 and the objects 320. The configuration 600 may include more or less than the above components.

The film or plate 630 is similar to the film or plate 530 in FIG. 5. The difference is that the film 630 is used to record an interference pattern 650 using the diffuse mirror 640. The diffuse mirror 640 may be any sheet metal or frosted glass. It is placed directly behind the film 630.

The laser source 510, the optical assembly 520, the chassis 310 and the objects 320 are the same as those shown in FIG. 5. In the configuration 600 in FIG. 6, the laser source 510 and the optical assembly 520 are placed at the same location of the optical sensor 350 when it is used for leak detection.

In the configuration 600, the laser beam from the laser source 510 passes through the film 630 and reflects off the diffuse mirror 630. The reflected beam then passes back through the film 630 and creates an interference pattern 650. The film 630 now has the interference pattern 650 and together they form an HOE to be used for leak detection as the HOE 340 shown in FIG. 3. When this HOE is placed on the bottom surface 314 in the inverted server 212 for leak detection, it is illuminated by the light source with emitted light at the same angle as the light reflected from the diffuse mirror 630 (during the creation of the interference pattern 650) at any location. The light will be diffracted back towards the sensor 350 which is placed at the same location at or near the focal point of the lens that was used to create the interference pattern 650. The result is the amount of fluorescence reflected from the dye in the drop to the optical sensor 350 +will be increased and the optical sensor 350 can reliably detect the leak.

In this configuration, it may be convenient to integrate the light source 330 that illuminates the dye (e.g., UV) and the laser source 510 that is used to created the HOE in a single unit. Additionally, the optical sensor 350 may also be integrated in the same unit so that the same unit can be used for creating the HOE 650 and for leak detection during operation.

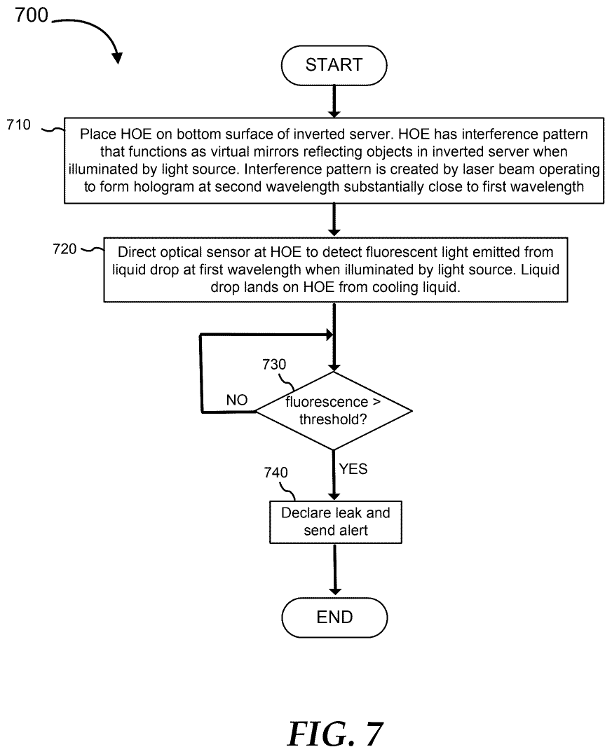

FIG. 7 is a flowchart illustrating a process 700 for holographic optical leak detection according to an embodiment of the present disclosure.

Upon START, the process 700 places an HOE on a bottom surface of an inverted server (Block 710). The HOE has an interference pattern that functions as mirrors in the inverted server when illuminated by a light source. The interference pattern is created by a laser beam operating to form a hologram at a laser wavelength substantially close to the first wavelength.

Next, the process 700 directs an optical sensor at the HOE to detect a fluorescent light emitted from a liquid drop at a fluorescence wavelength when illuminated by the light source (Block 720). The liquid drop lands on the HOE from a cooling liquid as result of a leak. The laser wavelength is substantially close to the fluorescence wavelength. The optical sensor collects the reflected fluorescent light emitted from the liquid drop.

Then the process 700 determines if the amount of the collected fluorescent light is greater than a predetermined threshold (Block 730). This predetermined threshold may be determined based on experiments or tests. If the amount of collected fluorescence is greater than the threshold, the process 700 declares that there is a leak an sends an alert to the user or an administrator (Block 740) and is then terminated. If the amount of collected fluorescence is not greater than the threshold, the process 700 declares that there is no leak and returns to block 730 to continue monitor the leak condition.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

The above-disclosed subject matter is to be considered illustrative, and not restrictive, and the appended claims are intended to cover any and all such modifications, enhancements, and other embodiments that fall within the scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. An apparatus comprising:
a holographic optical element (HOE) configured to have an interference pattern that functions as mirrors in an inverted server when illuminated by a light source, the HOE being placed on a bottom surface of the inverted server; and
an optical sensor directed at the HOE and configured to detect a fluorescent light emitted from a liquid drop at a first wavelength when illuminated by the light source, the liquid drop landing on the HOE from a cooling liquid,
wherein the interference pattern is created by a laser beam operating to form a hologram at a second wavelength substantially close to the first wavelength.

2. The apparatus of claim 1, wherein the HOE is a holographic film configured to record the interference pattern when placed on the bottom surface and exposed to the laser beam.

3. The apparatus of claim 2, wherein the mirrors are virtual mirrors reflecting the objects in the inverted server.

4. The apparatus of claim 2, wherein the holographic film is placed on a diffuse mirror when recording the interference pattern.

5. The apparatus of claim 3, wherein the diffuse mirror is a sheet of metal or frosted glass.

6. The apparatus of claim 1, wherein the objects in the inverted server are cooled by the cooling liquid mixed with a fluorescent dye, the cooling liquid flowing in a hose placed through the objects.

7. The apparatus of claim 1, wherein the objects in the inverted server are populated on a platform facing downward.

8. The apparatus of claim 1, wherein the bottom surface on which the HOE is disposed faces upward to the objects.

9. The apparatus of claim 1 wherein the optical sensor is positioned at or near a focal point of the virtual mirrors.

10. The apparatus of claim 6 wherein the liquid drop lands on the HOE from the cooling liquid as result of a leak.

11. A method comprising:
placing a holographic optical element (HOE) on a bottom surface of an inverted server, the HOE having an interference pattern that functions as mirrors in the inverted server when illuminated by a light source; and
directing an optical sensor at the HOE to detect a fluorescent light emitted from a liquid drop at a first wavelength when illuminated by the light source, the liquid drop landing on the HOE from a cooling liquid,
wherein the interference pattern is created by a laser beam operating to form a hologram at a second wavelength substantially close to the first wavelength.

12. The method of claim 11, wherein the HOE is a holographic film configured to record the interference pattern when placed on the bottom surface and exposed to the laser beam.

13. The method of claim 12, wherein the mirrors are virtual mirrors reflecting the objects in the inverted server.

14. The method of claim 12, wherein the holographic film is placed on a diffuse mirror when placed on the bottom surface and exposed to the laser beam.

15. The method of claim 13, wherein the diffuse mirror is a sheet of metal or frosted glass.

16. The method of claim 11, wherein the objects in the inverted server are cooled by the cooling liquid mixed with a fluorescent dye, the cooling liquid flowing in a hose placed through the objects.

17. The method of claim 11, wherein the objects in the inverted server are populated on a platform facing downward.

18. The method of claim 11, wherein the bottom surface on which the HOE is disposed faces upward to the objects.

19. The method of claim 11 wherein the optical sensor is positioned at or near a focal point of the virtual mirrors.

20. An information handling system, comprising:
a hose that transports cooling liquid mixed with a fluorescent dye in an inverted server; and
a leak detector comprising:
a holographic optical element (HOE) configured to have an interference pattern that functions as mirrors in the inverted server when illuminated by a light source, the HOE being placed on a bottom surface of the inverted server; and
an optical sensor directed at the HOE and configured to detect a fluorescent light emitted from a liquid drop at a first wavelength when illuminated by the light source, the liquid drop landing on the HOE from the cooling liquid,
wherein the interference pattern is created by a laser beam operating to form a hologram at a second wavelength substantially close to the first wavelength.
